(19) United States
(12) Patent Application Publication
(10) Pub. No.: US 2024/0079519 A1
(43) Pub. Date: Mar. 7, 2024

(54) C2 SYMMETRIC LED ELEMENT AND METHOD FOR MANUFACTURING DISPLAY MODULE BY USING ARRANGEMENT OF C2 SYMMETRIC LED ELEMENT USING WAVE ENERGY

(71) Applicant: Chungang University Industry Academic Cooperation Foundation, Seoul (KR)

(72) Inventors: Jae Soo YOO, Seoul (KR); Seong Hyeon NOH, Ulsan (KR)

(73) Assignee: Chungang University Industry Academic Cooperation Foundation, Seoul (KR)

(21) Appl. No.: 18/268,798

(22) PCT Filed: Dec. 22, 2021
(86) PCT No.: PCT/KR2021/019556

§ 371 Date: Jun. 21, 2023

(30) Foreign Application Priority Data
Dec. 22, 2020 (KR) 10-2020-0180938
Dec. 22, 2020 (KR) 10-2020-0181003

(51) Int. Cl. H01L 33/12; H01L 25/075; H01L 33/24; H01L 33/38

(52) U.S. Cl. CPC H01L 33/12; H01L 25/0753; H01L 33/24; H01L 33/382

(57) ABSTRACT

Disclosed is a LED device in which a plane of a substrate is patterned in a C2 symmetrical manner such that upper, lower, left, and right areas thereof are distinguished from each other. Further, in positioning the electrodes, one conductivity-type electrode is positioned on a center of the substrate, and electrodes of a conductivity-type different from that of the center electrode are positioned in an opposite manner to each other around the center electrode and are spaced from the center electrode by the same distance. Thus, even when the LED device is rotated by 180 degrees, the electrodes may match with each other. Further, disclosed are a method arranging C2 symmetrical LED devices using wave energy, and a method for fabricating a display module using the arranged C2 symmetrical LED devices. The C2 symmetrical LED device has the 180 degrees rotation symmetry. Thus, upper, lower, left, and right areas thereof are distinguished from each other, and thus, the devices may be oriented very accurately.

### FIELD

The present disclosure relates to a C2 symmetrical LED device. Further, the present disclosure relates to a method for arranging C2 symmetrical LED devices using wave energy, and a method for manufacturing a display module including C2 symmetrical LED devices arranged using wave energy.

In the present disclosure, the term “C2 symmetry” refers to an orientation of a molecule used when classifying molecular structures into groups in inorganic chemistry. A shape having the C2 symmetry looks the same under C2 rotation. The C2 symmetry refers to the 180-degree rotation symmetry. That is, the shape having the C2 symmetry looks the same when rotated by 180 degrees.

In the present disclosure, since the C2 symmetrical LED device has the 180-degree rotation symmetry, top, bottom, left, and right areas thereof are distinguished from each other, and the devices may be oriented very accurately.

Furthermore, the present disclosure provides a method of finding a suitable frequency to orient the C2 symmetrical LED device in a desired direction based on a size or a shape of the C2 symmetrical LED device, and of controlling the C2 symmetrical LED device via a combination of appropriate waveforms, and thus provides a method for efficiently manufacturing a display module.

### DESCRIPTION OF RELATED ART

When a blue light-emitting LED in which an GaN epitaxial layer is grown on a sapphire substrate is 100 μm or greater in size, a back side of an epitaxial layer is subjected to grinding such that a thickness of the sapphire substrate is smaller than 100 μm, and the resulting structure is subjected to cutting using a diamond knife or laser beam to form a chip. In this regard, when the griding is performed such that the thickness of the sapphire substrate is smaller than 60 μm, the grinding may give stress to the epitaxial layer, which may degrade performance. When the sapphire substrate is thick, it is not easy to shape the chip in a desired shape.

In order to solve this problem, a LLO (laser lift off) scheme is used to remove the sapphire and the epitaxial layer from each other to obtain a thickness of about 7 μm.

In a generally used LED chip, a wafer is patterned in a square or rectangular shape for easy processing, and then a backside of the wafer is ground to be thinner, and then the wafer is subjected to a sawing process with a diamond knife or laser beam. Thus, the chip is produced.

In order to implement a micro-LED display, it is necessary to quickly and accurately transfer multiple LED chips with a size of several tens of μm onto a substrate on which a circuit is disposed. At this time, the transferred LED chip is very small and thus is affected by a contact force with a transport plate or the substrate and should be handled very carefully to prevent damage to the chip due to static electricity.

A well-known scheme of transferring the microchips is a pick-and-place scheme. However, in this scheme, when the size of the chip is reduced to be smaller than several tens of μm, the chip transfer may be uncontrollable and thus the chip has to be transferred individually such that the transfer speed is very low.

An alternative scheme of transferring the microchips is a fluidic assembly (FA) scheme. However, in the FA scheme, 100% transfer of the chips is not achieved. Further, when a problem occurs in the once transferred chip, the transferred chip should be replaced. Thus, a lot of time is required in this process. In the FA scheme, the microchip is moved and fixed to a desired position using flow of fluid. Usually, when placing the microchip on the substrate, a molten lead is used to fix the chip, and in many cases, a contact between the molten lead and the chip depends on probability. Ultimately, the movement of the chip is not freely and intentionally controlled.

Furthermore, in the conventional scheme, the upper, lower, left, and right areas of the chip cannot be distinguished from each other. Thus, it is difficult to manufacture accurately a display device when the chips are rotated and oriented in different directions.

### PRESENT DISCLOSURE

### Technical Purpose

A purpose of the present disclosure is to provide a LED device in which a plane of a substrate is patterned in a C2 symmetrical manner such that upper, lower, left, and right areas thereof are distinguished from each other. In this case, in positioning the electrodes, one conductivity-type electrode is positioned on a center of the substrate, and electrodes of a conductivity-type different from that of the center electrode are positioned in an opposite manner to each other around the center electrode and are spaced from the center electrode by the same distance. Thus, even when the LED device is rotated by 180 degrees, the electrodes may match with each other.

Further, a purpose of the present disclosure is to provide a LED device in which a plane of a substrate is patterned in a C2 symmetrical manner such that upper, lower, left, and right areas thereof are distinguished from each other. In this case, in positioning the electrodes, one conductivity-type electrode is positioned on a center of the substrate, and portions of an electrode of a conductivity-type different from that of the center electrode and surrounding the center electrode are positioned in an opposite manner to each other around the center electrode and are spaced from the center electrode by the same distance. Thus, even when the LED device is rotated by 180 degrees, the electrodes may match with each other.

Furthermore, a purpose of the present disclosure is to provide a method for orienting the LED devices using wave energy to independently adjust the movement of each of the LED devices. In order to orient the C2 symmetrical LED device (microchip), the microchip may be moved and oriented in the desired direction via synthesis of the standing waves generated from the wave generator device.

### Technical Solution

A first aspect of the present disclosure provides a C2 symmetrical LED (Light Emitting Diode) device comprising: a substrate; a buffer layer disposed on the substrate; and an LED light-emitting element disposed on the buffer layer, wherein the LED light-emitting element has a stack structure in which a first conductivity-type semiconductor layer; a photoactive layer; and a second conductivity-type semiconductor layer are sequentially stacked, wherein a first conductivity-type electrode is disposed on the first conductivity-type semiconductor layer, while a second conductivity-type electrode is disposed on the second conductivity-type semiconductor layer, wherein the first conductivity-type electrode is spaced apart from the second conductivity-type electrode along a direction parallel to a plane of the substrate and is constructed to surround the second conductivity-type electrode, wherein the C2 symmetrical LED device has a 180-degrees rotation symmetry, wherein the C2 symmetrical LED device has the 180-degrees rotation symmetry, such that portions of the first conductivity-type electrode are positioned in an opposite manner to each other along the direction parallel to the plane of the substrate around the second conductivity-type electrode.

In one implementation of the first aspect, the substrate is a sapphire substrate.

In one implementation of the first aspect, the first conductivity-type semiconductor is one of an N-type semiconductor and a P-type semiconductor, while the second conductivity-type semiconductor is the other of the N-type semiconductor and the P-type semiconductor.

In one implementation of the first aspect, the C2 symmetrical LED device having the 180-degrees rotation symmetry has a parallelogram shape.

In one implementation of the first aspect, the portions of the first conductivity-type electrode positioned in the opposite manner to each other around the second conductivity-type electrode are spaced from the second conductivity-type electrode by the same spacing.

A second aspect of the present disclosure provides a C2 symmetrical LED device comprising: a substrate; a buffer layer disposed on the substrate; and an LED light-emitting element disposed on the buffer layer, wherein the LED light-emitting element has a stack structure in which a first conductivity-type semiconductor layer; a photoactive layer; and a second conductivity-type semiconductor layer are sequentially stacked, wherein two first conductivity-type electrodes are disposed on the first conductivity-type semiconductor layer, while a second conductivity-type electrode is disposed on the second conductivity-type semiconductor layer, wherein the two first conductivity-type electrodes are spaced apart from the second conductivity-type electrode along a direction parallel to a plane of the substrate, wherein the C2 symmetrical LED device has a 180-degrees rotation symmetry, wherein the C2 symmetrical LED device has the 180-degrees rotation symmetry, such that the two first conductivity-type electrodes are positioned in an opposite manner to each other along the direction parallel to the plane of the substrate around the second conductivity-type electrode.

In one implementation of the second aspect, the substrate is a sapphire substrate.

In one implementation of the second aspect, the first conductivity-type semiconductor is one of an N-type semiconductor and a P-type semiconductor, while the second conductivity-type semiconductor is the other of the N-type semiconductor and the P-type semiconductor.

In one implementation of the second aspect, the C2 symmetrical LED device having the 180-degrees rotation symmetry has a parallelogram shape.

In one implementation of the second aspect, the two first conductivity-type electrode positioned in the opposite manner to each other around the second conductivity-type electrode are spaced from the second conductivity-type electrode by the same spacing.

A third aspect of the present disclosure provides a method for arranging C2 symmetrical LED devices using wave energy, the method comprising: providing a wave generator device including at least one wave generator capable of generating a sound wave; placing a transport plate on the wave generator device, wherein n×m openings have been formed in the transport plate, wherein each of n and m is an integer number equal to or greater than 1; placing a plurality of C2 symmetrical LED devices on the transport plate, wherein the plurality of C2 symmetrical LED devices are adapted to be respectively seated in the openings; and generating a wave using the wave generator device to allow the C2 symmetrical LED devices to be respectively seated in the openings, wherein each of the C2 symmetrical LED devices includes: a substrate; a buffer layer disposed on the substrate; and an LED light-emitting element disposed on the buffer layer, wherein the LED light-emitting element has a stack structure in which a first conductivity-type semiconductor layer; a photoactive layer; and a second conductivity-type semiconductor layer are sequentially stacked, wherein a first conductivity-type electrode is disposed on the first conductivity-type semiconductor layer, while a second conductivity-type electrode is disposed on the second conductivity-type semiconductor layer, wherein the first conductivity-type electrode is spaced apart from the second conductivity-type electrode along a direction parallel to a plane of the substrate and is constructed to surround the second conductivity-type electrode, wherein the C2 symmetrical LED device has a 180-degrees rotation symmetry, wherein the C2 symmetrical LED device has the 180-degrees rotation symmetry, such that portions of the first conductivity-type electrode are positioned in an opposite manner to each other along the direction parallel to the plane of the substrate around the second conductivity-type electrode.

In one implementation of the third aspect, a shape of each of the opening has a shape identical to a shape of each of the C2 symmetrical LED devices such that each C2 symmetrical LED device is seated in each opening.

In one implementation of the third aspect, the n×m openings are arranged so as to be spaced from each other by the same spacing.

In one implementation of the third aspect, the opening is a through-opening extending through the transport plate.

In one implementation of the third aspect, when the opening is the through-opening, a support film is disposed under the transport plate so that the C2 symmetrical LED device is seated in the opening.

In one implementation of the third aspect, generating the wave using the wave generator device to allow the C2 symmetrical LED devices to be respectively seated in the openings includes generating the wave using the wave generator device to allow the C2 symmetrical LED devices received in fluid to be respectively seated in the openings.

In one implementation of the third aspect, the fluid is one of acetone, alcohol or water.

In one implementation of the third aspect, generating the wave using the wave generator device to allow the C2 symmetrical LED devices to be respectively seated in the openings includes changing a frequency of the wave generated from the wave generator device.

A fourth aspect of the present disclosure provides a method for manufacturing a display module using C2 symmetrical LED devices arranged using wave energy, the method comprising: a substrate on which n×m electrode patterns are formed, wherein each of n and m is an integer number equal to or greater than 1; applying a conductive paste on the substrate on which the electrode patterns have been formed, wherein the conductive paste is used to bond the C2 symmetrical LED devices and the electrode patterns to each other; positioning the substrate on a transport plate, wherein the C2 symmetrical LED devices have been respectively seated in n×m openings defined in the transport plate according to the method of one of claims 1 to 8, wherein each of n and m is an integer number equal to or greater than 1; and transferring the C2 symmetrical LED devices seated in the transport plate to the substrate on which the paste has been applied, and then performing heat treatment on the paste.

In one implementation of the fourth aspect, each of the electrode patterns formed on the substrate corresponds to each pixel.

In one implementation of the fourth aspect, positioning the substrate on the transport plate includes positioning the substrate on the transport plate such that the n×m openings of the transport plate respectively overlap the n×m electrode patterns preformed on the substrate.

### Technical Effect

According to the present disclosure, the C2 symmetrical LED device may be provided. Thus, the LED device in which the upper, lower, left, and right areas thereof may be distinguished from each other. Thus, even when the LED device is rotated by 180 degrees, the electrodes may match with each other.

When the transfer process according to the present disclosure is used, defective chips may be completely excluded before the transfer thereof to a driving substrate. Thus, the chips may be transferred to the driving substrate relatively quickly. The advantages of the present disclosure are expected to contribute to the commercialization of mini-LED displays and micro-LED displays in the future.

### BRIEF DESCRIPTION OF THE DRAWINGS

FIG. 1 shows a cross-sectional view of a GaN-based LED device.

FIG. 2 and FIG. 3 show top views of C2 symmetrical LED devices according to one embodiment of the present disclosure, respectively.

FIG. 4 shows a schematic diagram of a scheme in which the LED device is seated in a groove having a shape corresponding to a shape of the device according to an embodiment of the present disclosure.

FIG. 5 shows a top view of a C2 symmetrical LED device according to a further embodiment of the present disclosure.

FIG. 6 shows a top view of a C2 symmetrical LED device according to a further embodiment of the present disclosure.

FIG. 7 shows one embodiment of a wave generator device used in the present disclosure, and arrangement of C2 symmetrical LED devices using the wave generator device.

FIG. 8 shows a flowchart of a method of arranging C2 symmetrical LED devices using wave energy according to an embodiment of the present disclosure.

FIG. 9 shows a schematic plan view of a wave generator device according to an embodiment of the present disclosure.

FIG. 10 shows a plan view of a transport plate according to an embodiment of the present disclosure.

FIG. 11 is a schematic diagram for illustrating a scheme for generating a wave while the C2 symmetrical LED devices are dispersed in fluid, according to an embodiment of the present disclosure.

FIG. 12 is a schematic diagram of a state in which all of the C2 symmetrical LED device are respectively seated in openings of the transport plate.

FIG. 13 shows a flowchart of a method for manufacturing a display module using C2 symmetrical LED devices arranged using wave energy according to an embodiment of the present disclosure.

FIG. 14 shows a schematic diagram of a method for manufacturing a display module using C2 symmetrical LED devices arranged using wave energy according to an embodiment of the present disclosure.

Various embodiments are now described with reference to the drawings, wherein like reference numbers are used throughout the drawings to indicate like elements. In the present disclosure, various descriptions are presented to provide an understanding of the present disclosure. However, it is apparent that these embodiments may be practiced without the specific details. In other instances, each of well-known structures and devices is presented as a block diagram in order to facilitate describing the embodiments.

### DETAILED DESCRIPTIONS

Hereinafter, embodiments of the present disclosure will be described in detail with reference to the accompanying drawings. The present disclosure may have various changes and may have various forms. Thus, specific embodiments are illustrated in the drawings and described in detail in the text. However, this is not intended to limit the present disclosure to the specific forms as disclosed. It should be appreciated that the present disclosure includes all modifications, equivalents, or substitutes included in the spirit and scope of the present disclosure. Like reference numerals have been used for like components throughout the descriptions of the drawings.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, and/or components, but do not preclude the presence or addition of one or more other features, integers, operations, components, and/or portions thereof.

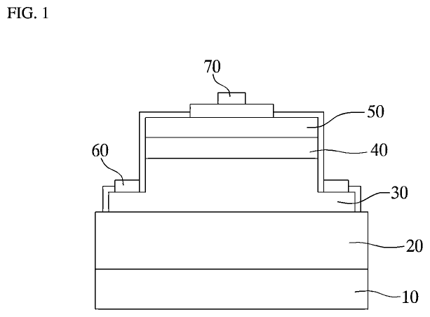

FIG. 1 shows a cross-sectional view of a GaN-based LED device. As shown in FIG. 1, a typical GaN-based LED device includes a substrate 10; a buffer layer 20; an N-type GaN layer 30; a photoactive layer 40; a P-type GaN layer 50; an N-type electrode 60, and a P-type electrode 70. In general, after sequentially crystal-growing the buffer layer 20, the N-type GaN layer 30, the active layer (InGaN or GaN) 40, and the P-type GaN layer 50 on the substrate 10 to form a stack, the stack is partially etched to the N-type GaN layer 30 for formation of the N-type metal electrode 60. Then, a transparent electrode 15 is formed on the active layer as needed. A dielectric protective film (not shown) covers an area except for an electrode area. Then, the N-type metal electrode 60 and the P-type metal electrode 70 are deposited.

The present disclosure discloses a LED device in which a plane of the substrate is patterned in a C2 symmetrical manner such that upper, lower, left, and right areas thereof are distinguished from each other. In this case, in positioning the electrodes, one conductivity-type electrode is positioned on a center of the substrate, and electrodes of a conductivity-type different from that of the center electrode are positioned in an opposite manner to each other around the center electrode and are spaced from the center electrode by the same distance. Thus, even when the device is rotated by 180 degrees, the electrodes may match with each other.

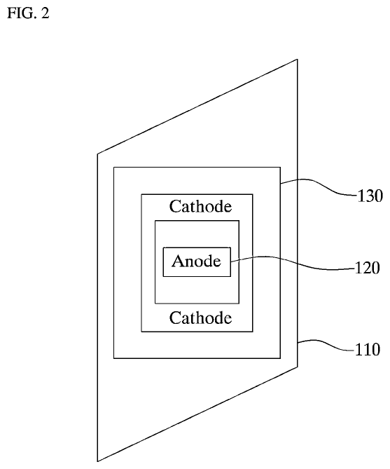

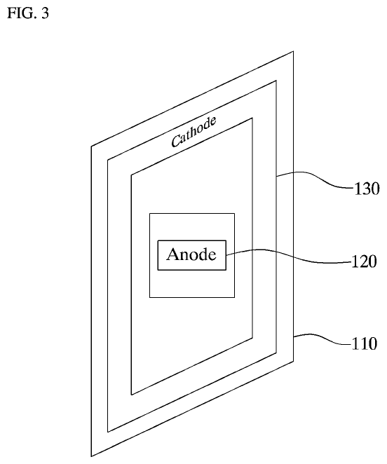

FIG. 2 and FIG. 3 show top views of C2 symmetrical LED devices according to one embodiment of the present disclosure, respectively.

A C2 symmetrical LED device according to an embodiment of the present disclosure includes a substrate; a buffer layer on the substrate; and an LED light-emitting element on the buffer layer, wherein the LED light-emitting element includes a stack in which a first conductivity-type semiconductor layer; a photoactive layer; and a second conductivity-type semiconductor layer are sequentially stacked. This stack has the same stack structure as described in FIG. 1. The substrate may be embodied as a sapphire substrate.

The first conductivity-type semiconductor is either N-type or P-type semiconductor, and the second conductivity-type semiconductor is a semiconductor of a different type from the first conductivity-type semiconductor. For example, when the first conductivity-type semiconductor is of the N-type, the second conductivity-type semiconductor is of the P-type.

A first conductivity-type electrode is positioned on top of the first conductivity-type semiconductor layer, and a second conductivity-type electrode is positioned on top of the second conductivity-type semiconductor layer. For example, when the first conductivity-type semiconductor is of the N-type, the first conductivity-type electrode may be an N-type electrode. When the second conductivity-type semiconductor is of the P-type, the second conductivity-type electrode may be a P-type electrode.

In one example, the first conductivity-type electrode is spaced apart from the second conductivity-type electrode along a direction parallel to the plane of the substrate and has a shape surrounding the second conductivity-type electrode. This configuration may be identified in FIG. 2 in which the first conductivity-type electrode 130 surrounds the second conductivity-type electrode 120. In one example, as shown in FIG. 3, the first conductivity-type electrode may have the same shape as that of the substrate.

As shown in FIG. 2 and FIG. 3, each of the C2 symmetrical LED devices has a 180-degrees rotation symmetry. A parallelogram shape has the 180-degrees rotation symmetry. As the C2 symmetrical LED device has the 180-degrees rotation symmetry, the first conductivity-type electrodes 130 are positioned in the opposite manner to each other in the direction parallel to the plane of the substrate around the second conductivity-type electrode 120 as the center electrode. In particular, based on FIG. 2 and FIG. 3, the first conductivity-type electrodes 130 are positioned on top of and under the second conductivity-type electrode 120, respectively. In this case, the distances of the first conductivity-type electrodes 130 from the second conductivity-type electrode are equal to each other. That is, it is preferable that the first conductivity-type electrodes are positioned in opposite to each other around the second conductivity-type electrode and are spaced from a center of the second conductivity-type electrode by the same distance along the direction parallel to the plane of the substrate. Due to this arrangement, even when the device in a form of a parallelogram is rotated by 180 degrees, the first conductivity-type electrode 130 are positioned in opposite to each other around the second conductivity-type electrode 120 and are spaced from a center of the second conductivity-type electrode 120 by the same distance along the direction parallel to the plane of the substrate. Thus, when the device is rotated by 180 degrees, the opposite electrodes may match each other.

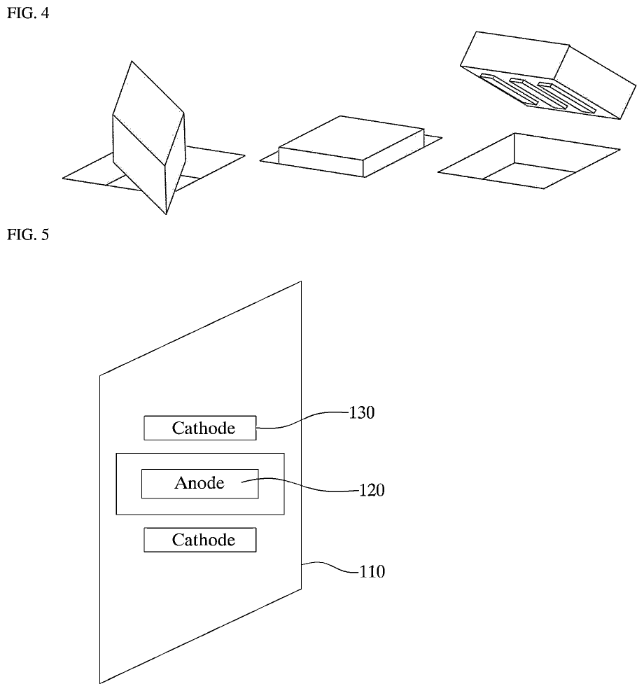

Thus, the top, bottom, left and right areas of the C2 symmetrical LED device are distinguished from each other. Thus, in arranging the C2 symmetrical LED devices for manufacturing the display device, even when each of the devices is rotated by 180 degrees, the opposite electrodes may match each other. In this regard, in manufacturing the display device, a groove is pre-formed in a transport plate. For example, when the device has a parallelogram shape, the corresponding groove has a parallelogram shape so that the C2 symmetrical LED device of the parallelogram fits the groove. Thus, when the device is seated in the groove, the electrode matching may be always achieved. This may be identified based on a way in which the C2 symmetrical LED device is seated in the groove of the shape corresponding to the shape of the C2 symmetrical LED device, as shown in FIG. 4. Thus, when the device is finally seated in the groove, the electrode matching is achieved.

FIG. 5 shows a top view of a C2 symmetrical LED device according to a further embodiment of the present disclosure. FIG. 5 is different from the embodiment of each of FIG. 2 and FIG. 3 only in terms of a form of the first conductivity-type electrode.

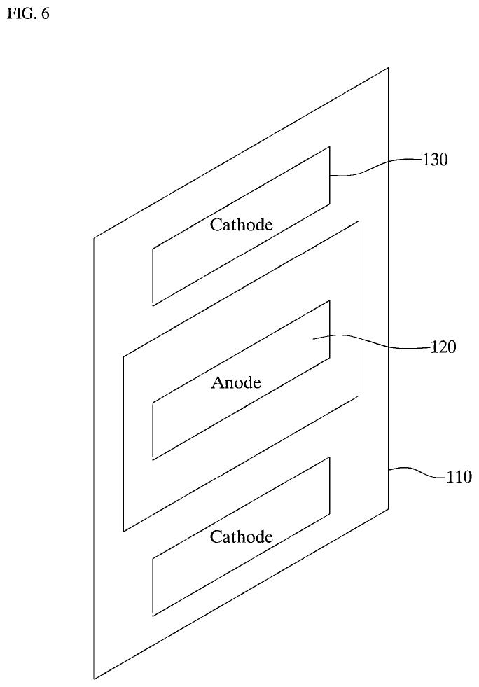

As shown in FIG. 5 and FIG. 6, the C2 symmetrical LED device has the 180-degrees rotation symmetry, wherein the C2 symmetrical LED device of the 180-degrees rotation symmetry has a parallelogram shape. As shown in FIG. 5, each of the electrodes 120 and 130 has a parallelogram shape similar to the shape of the C2 symmetrical LED device. Thus, as the C2 symmetrical LED device has the 180-degrees rotation symmetry, the first conductivity-type electrodes 130 are positioned in the opposite manner to each other along the direction parallel to the substrate plane around the second conductivity-type electrode 120.

The C2 symmetrical LED device according to an embodiment of the present disclosure includes the substrate; the buffer layer on the substrate; and the LED light-emitting element on the buffer layer, wherein the LED light-emitting element has a stack in which the first conductivity-type semiconductor layer; the photoactive layer; and the second conductivity-type semiconductor layer are sequentially stacked. This stack structure has the same stack structure as described in FIG. 1.

The substrate may be embodied as a sapphire substrate.

The first conductivity-type semiconductor is either N-type or P-type semiconductor, and the second conductivity-type semiconductor is a semiconductor of a different type from the first conductivity-type semiconductor. For example, when the first conductivity-type semiconductor is of the N-type, the second conductivity-type semiconductor is of the P-type.

A first conductivity-type electrode is positioned on top of the first conductivity-type semiconductor layer, and a second conductivity-type electrode is positioned on top of the second conductivity-type semiconductor layer. For example, when the first conductivity-type semiconductor is of the N-type, the first conductivity-type electrode may be an N-type electrode. When the second conductivity-type semiconductor is of the P-type, the second conductivity-type electrode may be a P-type electrode.

As shown in FIG. 5, the C2 symmetrical LED device has a 180-degrees rotation symmetry. A parallelogram shape has the 180-degrees rotation symmetry. As the C2 symmetrical LED device has the 180-degrees rotation symmetry, the first conductivity-type electrodes 130 are positioned in the opposite manner to each other in the direction parallel to the plane of the substrate around the second conductivity-type electrode 120 as the center electrode. In particular, based on FIG. 5, the first conductivity-type electrodes 130 are positioned on top of and under the second conductivity-type electrode 120, respectively. In this case, the distances of the first conductivity-type electrodes 130 from the second conductivity-type electrode are equal to each other. That is, it is preferable that the first conductivity-type electrodes are positioned in opposite to each other around the second conductivity-type electrode and are spaced from a center of the second conductivity-type electrode by the same distance along the direction parallel to the plane of the substrate. Due to this arrangement, even when the device in a form of a parallelogram is rotated by 180 degrees, the first conductivity-type electrode 130 are positioned in opposite to each other around the second conductivity-type electrode 120 and are spaced from a center of the second conductivity-type electrode 120 by the same distance along the direction parallel to the plane of the substrate. Thus, when the device is rotated by 180 degrees, the opposite electrodes may match each other.

FIG. 6 shows a top view of a C2 symmetrical LED device according to a further embodiment of the present disclosure. As shown in FIG. 6, the C2 symmetrical LED device has a 180-degrees rotation symmetry. Each of the electrodes 120 and 130 has a parallelogram shape similar to the shape of the C2 symmetrical LED device. The parallelogram shape has the 180-degrees rotation symmetry. As the C2 symmetrical LED device has the 180-degrees rotation symmetry, the first conductivity-type electrodes 130 are positioned in the opposite manner to each other in the direction parallel to the plane of the substrate around the second conductivity-type electrode 120 as the center electrode. In particular, based on FIG. 6, the first conductivity-type electrodes 130 are positioned on top of and under the second conductivity-type electrode 120, respectively. In this case, the distances of the first conductivity-type electrodes 130 from the second conductivity-type electrode are equal to each other. That is, it is preferable that the first conductivity-type electrodes are positioned in opposite to each other around the second conductivity-type electrode and are spaced from a center of the second conductivity-type electrode by the same distance along the direction parallel to the plane of the substrate. Due to this arrangement, even when the device in a form of a parallelogram is rotated by 180 degrees, the first conductivity-type electrode 130 are positioned in opposite to each other around the second conductivity-type electrode 120 and are spaced from a center of the second conductivity-type electrode 120 by the same distance along the direction parallel to the plane of the substrate. Thus, when the device is rotated by 180 degrees, the opposite electrodes may match each other.

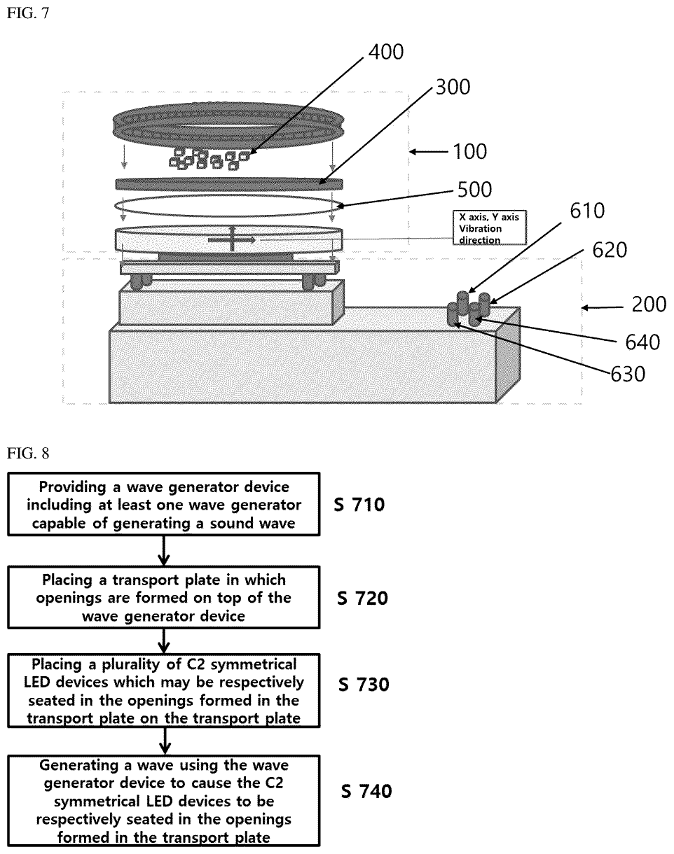

FIG. 7 shows an example of a wave generator device and a microchip array used in the present disclosure. As shown in FIG. 7, the wave generator device used in the present disclosure has a chuck area 100 and a wave generator device area 200.

In the chuck area 100, a chuck is assembled. In a process of assembling the chuck, microchips (C2 symmetrical LED devices) 400 are placed on the transport plate 300 and assembled. In this case, when the transport plate has a through-opening defined therein, the C2 symmetrical LED devices may escape through the opening. For this reason, an additional film 500 may be disposed under the transport plate 300. However, when the opening is not the through-opening or when the opening is shaped so that the C2 symmetrical LED device does not escape therethrough downwardly (for example, a diameter of the opening decreases as the opening extends downwardly, or a diameter of the opening is smaller than a size of the microchip), the film 500 is not required.

The assembled chuck is fastened to the wave generator device 200. In accordance with the present disclosure, the wave generator device may generate an appropriate waveform based on change in a frequency and a boundary of a medium (in this example, the substrate) in which the waveform is generated. The wave generator device may adjust an amplitude of the wave. In one example of the present disclosure, four waveform generators 610, 620, 630, and 640 are installed which operate independently from each other to generate a synthesized waveform. The synthesized waveform may travel in an x-axis and a y-axis to allow the chip to be moved in a desired direction.

In accordance with the present disclosure, the C2 symmetrical LED devices are arranged using the wave generator device as described in FIG. 7. FIG. 8 shows a flowchart of a method of arranging the C2 symmetrical LED devices using wave energy according to an embodiment of the present disclosure.

As shown in FIG. 8, the method of arranging the microchips using wave energy according to an embodiment of the disclosure includes providing a wave generator device including at least one wave generator capable of generating a sound wave in S710; placing a transport plate in which n×m (each of n and m is an integer number greater than or equal to 1) openings are formed on top of the wave generator device in S720; placing a plurality of C2 symmetrical LED devices which may be respectively seated in the openings formed in the transport plate on the transport plate in S730; and generating a wave using the wave generator device to cause the C2 symmetrical LED devices to be respectively seated in the openings formed in the transport plate in S740.

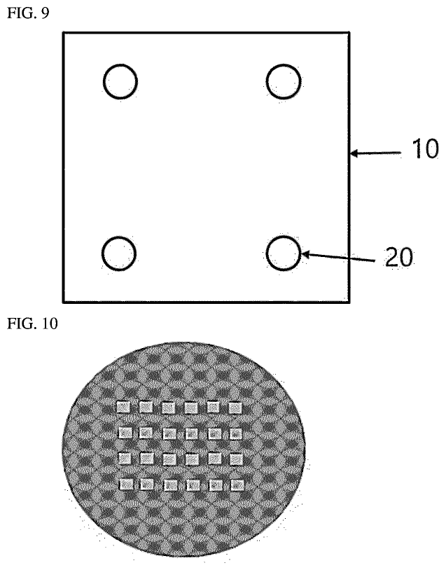

In S710, the wave generator device including at least one wave generator capable of generating the sound waves is prepared. At least one wave generator may be required, or a plurality of wave generators may be used. FIG. 9 shows a schematic plan view of the wave generator device according to an embodiment of the present disclosure. As shown in FIG. 9, four wave generators 20 may be positioned on the support plate 10. In this case, two of the four wave generators 20 may be controlled in a paired manner. The two pairs of wave generators may be controlled such that waves may be generated in an overlapping manner.

In S720, the transport plate is positioned on the wave generator device This transport plate has the n×m (each of n and m is an integer number greater than or equal to 1) openings defined therein. The shape of the opening may be the same as the shape of the C2 symmetrical LED device such that the C2 symmetrical LED device may be received in the opening. Thus, when the C2 symmetrical LED device has a parallelogram shape, the shape of the opening is the parallelogram shape.

FIG. 10 shows a plan view of a transport plate according to an embodiment of the present disclosure. FIG. 10 shows an example of the transport plate including 6×4 openings. As shown in FIG. 10, the openings may be arranged and spaced from each other by an equal spacing. As described above, the opening of the transport plate may be the through-opening. In this case, there is a possibility that the C2 symmetrical LED device may escape through the opening. For this reason, the additional film 500 may be positioned under the transport plate.

In S730, the plurality of C2 symmetrical LED devices which may be respectively seated in the openings formed in the transport plate are placed on the transport plate. Each of the C2 symmetrical LED devices may have a size in a range of about 5 μm to 300 μm.

In S740, the wave is generated using the wave generator device to cause the C2 symmetrical LED devices to be respectively seated in the openings formed in the transport plate. To this end, the openings may be formed in the transport plate based on the sizes of the C2 symmetrical LED devices to be used, and then, the C2 symmetrical LED devices may be respectively seated into the openings of the transport plate using the wave generator device.

In this case, the C2 symmetrical LED device may be well seated in the opening formed in the transport plate using fluid 700. Any one of acetone, methanol and water may be used as the fluid. It is desirable to seat the C2 symmetrical LED device into the opening of the transport plate by generating the wave while the C2 symmetrical LED devices are dispersed in the fluid 700.

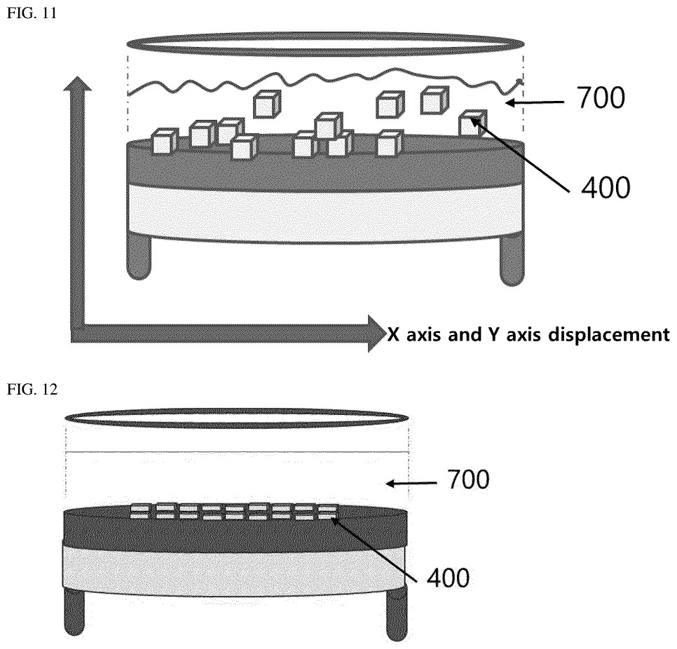

FIG. 11 is a schematic diagram for illustrating a method for seating the C2 symmetrical LED device into the opening of the transport plate by generating the wave while the C2 symmetrical LED devices are dispersed in the fluid, according to an embodiment of the present disclosure. FIG. 12 is a schematic diagram of a state in which all of the C2 symmetrical LED device are respectively seated in the openings of the transport plate.

Furthermore, while changing the frequency of the waveform generated from the wave generator device, the C2 symmetrical LED devices may be respectively seated in the openings formed in the transport plate. Changing the frequency of the waveform generated from the wave generator device may allow a new resonant wave to be generated, such that the C2 symmetrical LED devices move, thereby increasing the probability that the C2 symmetrical LED devices are respectively seated in the openings of the transport plate. Furthermore, in accordance with the present disclosure, the C2 symmetrical LED device is used and the opening of the transport plate also has a corresponding shape to the shape of the C2 symmetrical LED device. Thus, when the C2 symmetrical LED devices are respectively seated in the openings in a state in which the C2 symmetrical LED devices are rotated by 180 degrees, electrode matching may be achieved. While continuously changing the frequency to change the waveform, all the microchips are respectively seated in the openings. The changing of the frequency may be controlled based on the shape and the size of the C2 symmetrical LED device, the shape of the opening, and the number of chips.

The seating of the C2 symmetrical LED devices respectively in the openings of the transport plate has been described above. Hereinafter, a method for manufacturing the display module by transferring the arranged C2 symmetrical LED device to a substrate on which a driver circuit has been printed will be described.

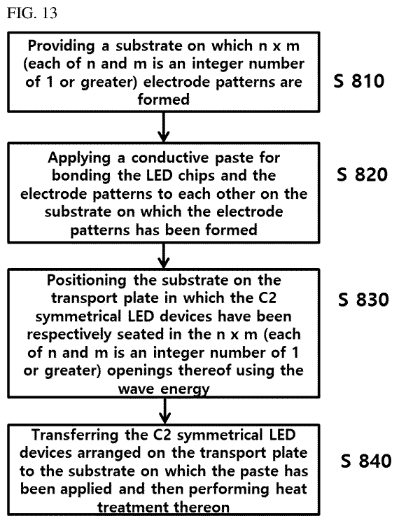

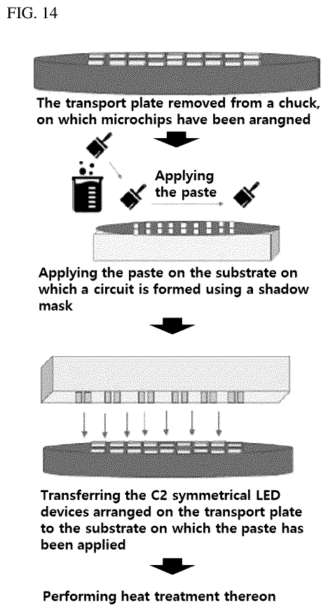

FIG. 13 shows a flowchart of a method for manufacturing a display module using C2 symmetrical LED devices arranged using wave energy according to an embodiment of the present disclosure. FIG. 14 shows a schematic diagram of a method for manufacturing a display module using C2 symmetrical LED devices arranged using wave energy according to an embodiment of the present disclosure.

As shown in FIG. 13, the method for manufacturing the display module using C2 symmetrical LED devices arranged using wave energy according to an embodiment of the present disclosure includes providing a substrate on which n×m (each of n and m is an integer number of 1 or greater) electrode patterns are formed in S810; applying a conductive paste for bonding the LED chips and the electrode patterns to each other on the substrate on which the electrode patterns has been formed in S820; positioning the substrate on the transport plate in which the C2 symmetrical LED devices have been respectively seated in the n×m (each of n and m is an integer number of 1 or greater) openings thereof using the wave energy in S830; and transferring the C2 symmetrical LED devices arranged on the transport plate to the substrate on which the paste has been applied and then performing heat treatment thereon in S840.

In S810, the substrate on which n×m (each of n and m is an integer number of 1 or greater) electrode patterns have been formed may be provided. Then number of the electrode patterns formed on the substrate may be equal to the number of C2 symmetrical LED devices respectively seated in the openings (the n×m openings) of the transport plate. Each electrode pattern is formed to positionally-correspond to each C2 symmetrical LED device. Therefore, in each pixel, each electrode pattern formed on the substrate is connected to each C2 symmetrical LED device. That is, in one pixel, one electrode pattern corresponding to one C2 symmetrical LED device is formed on the substrate. In this case, the electrode patterns are arranged in the same manner in which the electrodes of the C2 symmetrical LED device are arranged. That is, the both electrode patterns are positioned in the opposite manner to each other around a center electrode pattern and are spaced from the center electrode pattern by the same spacing. The substrate may be made of glass, silicon wafer, or plastic. However, the present disclosure is not limited thereto.

In S820, the conductive paste is applied to the electrode patterns on the substrate to which the LED devices are to be attached. An adhesive paste may be applied to a position where each electrode is to be positioned. In accordance with the present disclosure, the paste is applied into a gap using a shadow mask. In this case, the generally used conductive film (ACF) may be used.

In S830, the substrate prepared in S820 may be placed on the transport plate in which the C2 symmetrical LED devices have been respectively seated in the n×m (each of n and m is an integer number of 1 or greater) openings thereof using the wave energy. In this case, the substrate prepared in S820 may be placed on the transport plate such that n×m openings of the transport plate positionally correspond to the n×m electrode patterns pre-formed on the substrate to form pixels.

In S840, the C2 symmetrical LED devices on the transport plate may be respectively transferred to the substrate so as to correspond to the electron patterns, and the bonded substrate to the transport plate may be heat-treated. After the heat treatment, the plastic substrate and the transport plate are removed from each other.

In this way, the display module is manufactured according to the method for manufacturing the display module using the C2 symmetrical LED devices arranged using the wave energy. In this case, the C2 symmetrical LED device may be embodied as a micro-LED chip, and in this case, the display module may be embodied as an LED display module. A size of the microchip may be in a range from 5 μm to 300 μm. The display module may be manufactured by transferring the micro-LED to the substrate according to the method of the present disclosure. Then, the display device may be finally manufactured using this display module.

Although the present disclosure has been described with reference to preferred embodiments of the present disclosure, those skilled in the art will understand that various modifications and changes may be made to the present disclosure without departing from the spirit and scope of the present disclosure as described in the claims below.

1. A C2 symmetrical LED (Light Emitting Diode) device comprising:
a substrate;
a buffer layer disposed on the substrate; and
an LED light-emitting element disposed on the buffer layer,
wherein the LED light-emitting element has a stack structure in which a first conductivity-type semiconductor layer; a photoactive layer; and a second conductivity-type semiconductor layer are sequentially stacked,
wherein a first conductivity-type electrode is disposed on the first conductivity-type semiconductor layer, while a second conductivity-type electrode is disposed on the second conductivity-type semiconductor layer,
wherein the first conductivity-type electrode is spaced apart from the second conductivity-type electrode along a direction parallel to a plane of the substrate and is constructed to surround the second conductivity-type electrode,
wherein the C2 symmetrical LED device has a 180-degrees rotation symmetry,
wherein the C2 symmetrical LED device has the 180-degrees rotation symmetry, such that portions of the first conductivity-type electrode are positioned in an opposite manner to each other along the direction parallel to the plane of the substrate around the second conductivity-type electrode.

2. The C2 symmetrical LED device of claim 1, wherein the substrate is a sapphire substrate.

3. The C2 symmetrical LED device of claim 1, wherein the first conductivity-type semiconductor is one of an N-type semiconductor and a P-type semiconductor, while the second conductivity-type semiconductor is the other of the N-type semiconductor and the P-type semiconductor.

4. The C2 symmetrical LED device of claim 1, wherein the C2 symmetrical LED device having the 180-degrees rotation symmetry has a parallelogram shape.

5. The C2 symmetrical LED device of claim 1, wherein the portions of the first conductivity-type electrode positioned in the opposite manner to each other around the second conductivity-type electrode are spaced from the second conductivity-type electrode by the same spacing.

6. A C2 symmetrical LED device comprising:
a substrate;
a buffer layer disposed on the substrate; and
an LED light-emitting element disposed on the buffer layer,
wherein the LED light-emitting element has a stack structure in which a first conductivity-type semiconductor layer; a photoactive layer; and a second conductivity-type semiconductor layer are sequentially stacked,
wherein two first conductivity-type electrodes are disposed on the first conductivity-type semiconductor layer, while a second conductivity-type electrode is disposed on the second conductivity-type semiconductor layer,
wherein the two first conductivity-type electrodes are spaced apart from the second conductivity-type electrode along a direction parallel to a plane of the substrate,
wherein the C2 symmetrical LED device has a 180-degrees rotation symmetry,
wherein the C2 symmetrical LED device has the 180-degrees rotation symmetry, such that the two first conductivity-type electrodes are positioned in an opposite manner to each other along the direction parallel to the plane of the substrate around the second conductivity-type electrode.

7. The C2 symmetrical LED device of claim 6, wherein the substrate is a sapphire substrate.

8. The C2 symmetrical LED device of claim 6, wherein the first conductivity-type semiconductor is one of an N-type semiconductor and a P-type semiconductor, while the second conductivity-type semiconductor is the other of the N-type semiconductor and the P-type semiconductor.

9. The C2 symmetrical LED device of claim 6, wherein the C2 symmetrical LED device having the 180-degrees rotation symmetry has a parallelogram shape.

10. The C2 symmetrical LED device of claim 6, wherein the two first conductivity-type electrode positioned in the opposite manner to each other around the second conductivity-type electrode are spaced from the second conductivity-type electrode by the same spacing.

11. A method for arranging C2 symmetrical LED devices using wave energy, the method comprising:
providing a wave generator device including at least one wave generator capable of generating a sound wave;
placing a transport plate on the wave generator device, wherein n×m openings have been formed in the transport plate, wherein each of n and m is an integer number equal to or greater than 1;
placing a plurality of C2 symmetrical LED devices on the transport plate, wherein the plurality of C2 symmetrical LED devices are adapted to be respectively seated in the openings; and
generating a wave using the wave generator device to allow the C2 symmetrical LED devices to be respectively seated in the openings,
wherein each of the C2 symmetrical LED devices includes:
a substrate;
a buffer layer disposed on the substrate; and
an LED light-emitting element disposed on the buffer layer,
wherein the LED light-emitting element has a stack structure in which a first conductivity-type semiconductor layer; a photoactive layer; and a second conductivity-type semiconductor layer are sequentially stacked,
wherein a first conductivity-type electrode is disposed on the first conductivity-type semiconductor layer, while a second conductivity-type electrode is disposed on the second conductivity-type semiconductor layer,
wherein the first conductivity-type electrode is spaced apart from the second conductivity-type electrode along a direction parallel to a plane of the substrate and is constructed to surround the second conductivity-type electrode,
wherein the C2 symmetrical LED device has a 180-degrees rotation symmetry,
wherein the C2 symmetrical LED device has the 180-degrees rotation symmetry, such that portions of the first conductivity-type electrode are positioned in an opposite manner to each other along the direction parallel to the plane of the substrate around the second conductivity-type electrode.

12. The method of claim 11, wherein a shape of each of the opening has a shape identical to a shape of each of the C2 symmetrical LED devices such that each C2 symmetrical LED device is seated in each opening.

13. The method of claim 11, wherein the n×m openings are arranged so as to be spaced from each other by the same spacing.

14. The method of claim 11, wherein the opening is a through-opening extending through the transport plate.

15. The method of claim 14, wherein when the opening is the through-opening, a support film is disposed under the transport plate so that the C2 symmetrical LED device is seated in the opening.

16. The method of claim 11, wherein generating the wave using the wave generator device to allow the C2 symmetrical LED devices to be respectively seated in the openings includes generating the wave using the wave generator device to allow the C2 symmetrical LED devices received in fluid to be respectively seated in the openings.

17. The method of claim 16, wherein the fluid is one of acetone, alcohol or water.

18. The method of claim 11, wherein generating the wave using the wave generator device to allow the C2 symmetrical LED devices to be respectively seated in the openings includes changing a frequency of the wave generated from the wave generator device.

19-22. (canceled)
